(19) United States
(12) Patent Application Publication
(10) Pub. No.: US 2020/0208265 A1
(43) Pub. Date: Jul. 2, 2020

(54) COATING APPARATUS AND COATING METHOD

(71) Applicant: AZTRONG INC., Hsin-Chu City (TW)

(72) Inventors: Chien-Te HSIEH, Taoyuan City (TW); Kuan-Tsae HUANG, Changhua County (TW); Peng-Yang LEE, Changhua County (TW); Chih-Chung MA, Changhua City (TW); Hwai-Jan WU, Taipei City (TW)

(73) Assignee: AZTRONG INC., Hsin-Chu City (TW)

(21) Appl. No.: 16/727,614

(22) Filed: Dec. 26, 2019

(30) Foreign Application Priority Data
Dec. 28, 2018 (TW) 107147655

(51) Int. Cl. C23C 16/455; H01M 4/04

(52) U.S. Cl. CPC C23C 16/45544; C23C 16/45565; H01M 4/0428

(57) ABSTRACT

A coating apparatus includes a material-supply device configured to supply a precursor and a reactant, a distribution device connected to the material-supply device, and a reactor connected to the distribution device. The distribution device is configured to distribute the precursor and the reactant into the reactor.

### CROSS-REFERENCE TO RELATED APPLICATIONS

This non-provisional application claims priority under 35 U.S.C. § 119(a) on Patent Application No(s). 107147655 filed in Taiwan R.O.C on Dec. 28th, 2018, the entire contents of which are hereby incorporated by reference.

### BACKGROUND

### 1. Technical Field

This present disclosure relates to a surface coating technology, more particular to a coating apparatus and a coating method related to fluidization.

### 2. Related Art

Conventionally, problems with lithium batteries are their capacity and stability. As the expansion and contraction of the electrode becomes serious, a damaged electrode reduces the conductivity and shortens the lifetime of lithium batteries.

In order to improve the capacity and lifetime of lithium batteries, one method is to coat the electrode with a metal oxide or highly conductive material.

### SUMMARY

According to one aspect of the present disclosure, a coating apparatus includes: a material-supply device configured to supply a precursor and a reactant; a distribution device connected to the material-supply device; and a reactor connected to the distribution device, the distribution device is configured to distribute the precursor and the reactant into the reactor.

According to another aspect of the present disclosure, a coating method includes:

providing a matrix particle; and performing a fluidized atomic layer deposition (FALD), wherein a mixture containing a precursor and an inert gas and a mixture containing a reactant and the inert gas are provided at a fluidization velocity to have the precursor and the reactant alternatively reacted on the surface of suspended matrix particle, obtain film-coated matrix particle.

### BRIEF DESCRIPTION OF THE DRAWINGS

FIG. 1 is a schematic view of a coating apparatus according to one embodiment of the present disclosure;

FIG. 2 is a perspective view of a distribution device in FIG. 1;

FIG. 3 is a coating apparatus according to another embodiment of the present disclosure;

FIG. 4 is a coating process according to one embodiment of the present disclosure;

FIG. 5 is a FALD flowchart of FIG. 4;

FIG. 6 is a graph of film mass against FALD cycle;

FIG. 7 is a graph of capacity retention of coated electrode against charge-discharge current;

FIG. 8 is a graph of specific capacity of coated electrode against charge-discharge cycle;

FIG. 9A is a SEM image of film-coated electrode material fabricated by the coating method in FIG. 4; and

FIG. 9B is a SEM image of film-coated electrode material fabricated by conventional fluidized bed reactor (FBR).

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

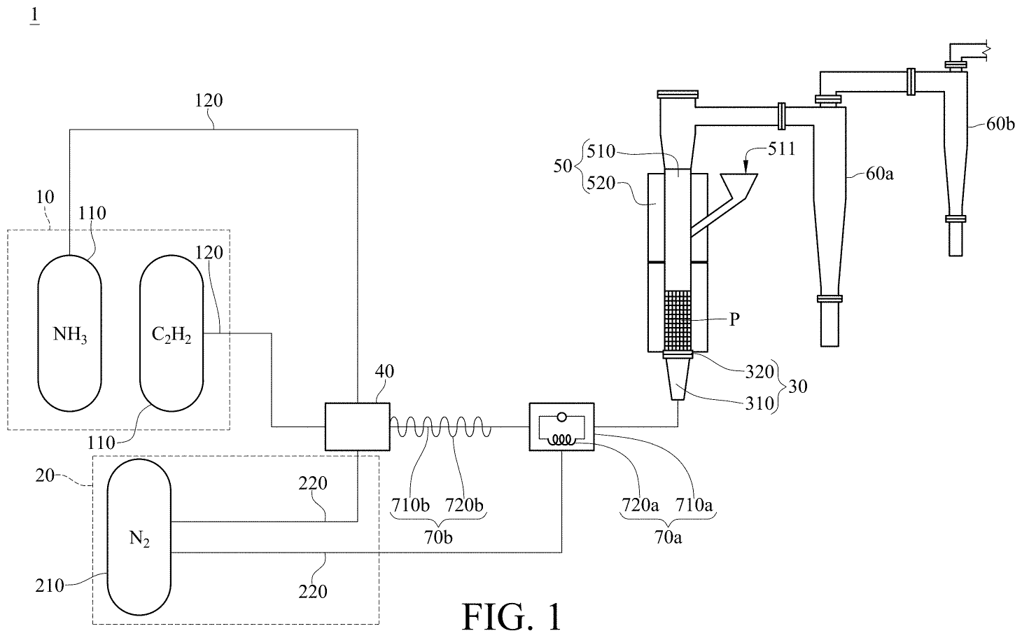

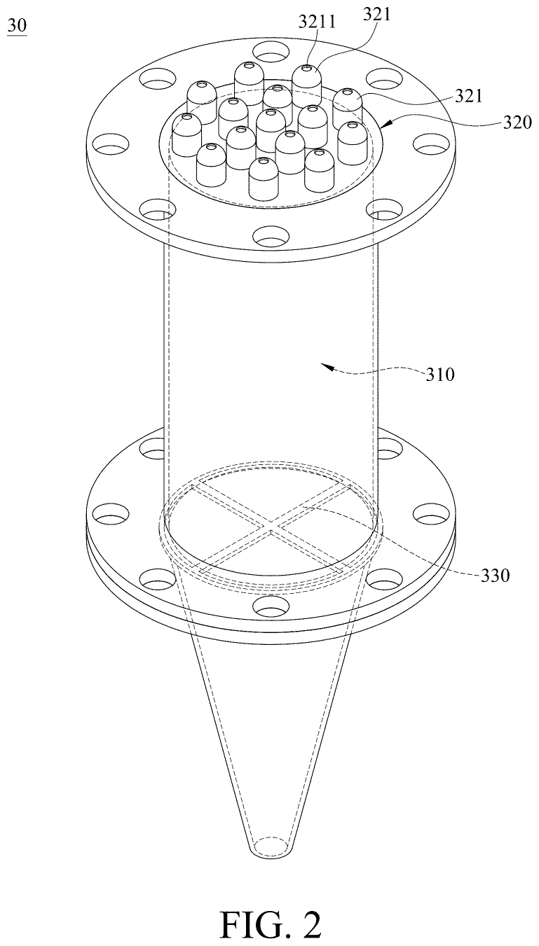

FIG. 1 is a schematic view of a coating apparatus according to one embodiment of the present disclosure. FIG. 2 is a perspective view of a distribution device in FIG. 1. In this embodiment, a coating apparatus 1 can include a material-supply device 10, a gas-supply device 20, a distribution device 30, a mixing-chamber 40, a reactor 50, two collectors 60a, 60b and a plurality of heating devices 70a, 70b.

The material-supply device 10 is configured to supply precursor and reactant. Specifically, the material-supply device 10 can include a plurality of containers 110 and a plurality of transporting-pipes 120 connected to the containers 110. The transporting-pipes 120 constitute a fluid transport path for precursor and reactant. The containers 110 store-precursors or reactants for atomic layer deposition (ALD). Said precursors and reactants can be gas, liquid or solid.

The gas-supply device 20 includes a gas-tank 210 and a plurality of transporting-pipes 220 connected to the gas-tank 210. The transporting-pipes 220 constitute a fluid transport path for inert gas. The gas-tank 210 stores an inert gas for ALD. Said inert gas, for example but not limited to, is nitrogen or argon.

The distribution device 30 is connected to the material-supply device 10 and the gas-supply device 20. Specifically, the distribution device 30 includes an inbound-chamber 310 and a distribution unit 320 connected to each other. The transporting-pipes 120 of the material-supply device 10 and the transporting-pipes 220 of the gas-supply device 20 are connected to the inbound-chamber 310. The precursor, the reactant and the inert gas can flow into the inbound-chamber 310 because transporting-pipes 120 and 220 are configured to connect material-supply device and gas-supply device. The distribution unit 320 includes a plurality of spray nozzles 321 arranged at intervals. The spray nozzles 321 can be cylindrical, and a cap 3211 is located on top of spray nozzles 321. A filter 330 is disposed in the inbound-chamber 310.

The mixing-chamber 40 is disposed on the interconnection of fluid transport path among the material-supply device 10, the distribution device 30, and the gas-supply device 20. In other embodiments, the precursor or the reactant mixes with the inert gas uniformly in the transporting-pipes, the mixing-chamber is not an essential element in the coating apparatus.

The reactor 50 is connected to the distribution device 30. In detail, the reactor 50 includes a reaction-chamber 510 and a heater 520 disposed in the reaction-chamber 510. The inbound-chamber 310 of the distribution device 30 is connected to the reaction-chamber 510 of the reactor 50 via the distribution unit 320. The heater 520 is configured to increase the temperature in the reaction-chamber 510 to facilitate the ALD.

In this embodiment, the reactor 50 is a reactor where a thin film is coated on the surface of particles by FALD reaction. Specifically, the particles are delivered into the reaction-chamber 510 from a feeding inlet 511. The precursor or a mixture of the precursor and the inert gas is distributed to the reaction-chamber 510 by the distribution device 30, and react with the surface of fluidized particles. Secondly, the reactant or a mixture of the reactant and the inert gas is distributed to the reaction-chamber 510 by the distribution device 30, and react with the precursor on the surface of fluidized particles. Thus, one FALD cycle is performed.

The collector 60a is connected to the reaction-chamber 510 of the reactor 50. When the FALD cycle is completed, the fluidized particles rotate into the collector 60a from the reaction-chamber 510, collide with the inner wall of the collector 60a and downward to the collection tank (not shown in the drawings). The fluid flows out of the collector 60a continuously.

The collector 60b is connected to the collector 60a. Some particles may remain in the fluid discharged from the collector 60a and rotate into the collector 60b, collide with the inner wall of the collector 60b, and are collected in another tank (not shown). The configuration of two collectors 60a and 60b prevents the particles loss from incomplete collection, thereby improving production efficiency of the reactor 50. The Collector 60a and 60b is, for example but not limited to, a cyclone separator, and the number of collectors is not limited in the present disclosure.

The heating device 70a may include a heating-chamber 710a and a heater 720a in the heating-chamber 710a. The heating-chamber 710a is connected to the inbound-chamber 310 of the distribution device 30, the mixing-chamber 40 and the transporting-pipe 220 of the gas-supply device 20.

The heating device 70b may include a transporting-pipe 710b and a heater 720b surrounding the transporting-pipe 710b. The transporting-pipe 710b is connected to the mixing-chamber 40 and the heating-chamber 710a of the heating device 70a.

In this embodiment, the heater 520 is a circular heating plate surrounding the reaction-chamber 510, and the heaters 720a, 720b is a serpentine coil heater. The type and the number of the heaters are not limited in this disclosure. The heaters 520, 720a, 720b are configured to heat the precursor, the reactant and the inert gas to a temperature suitable for ALD.

The coating apparatus 1 may include one or more blowers (not shown) to increase the flow velocity of coating apparatus 1. The blowers, for example but not limited to, are connected to the inbound-chamber 310 of the distribution device 30.

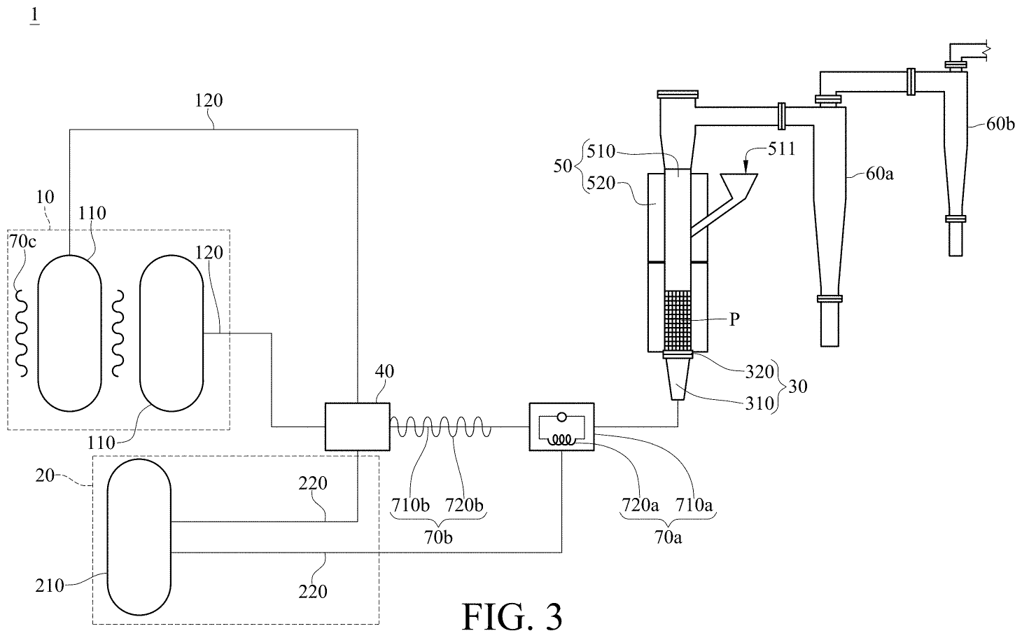

FIG. 3 is a coating apparatus according to another embodiment of the present disclosure. The coating apparatus 1 in this embodiment further includes a heating device 70c disposed on the material-supply device 10. The precursor can be liquid or solid. The precursor is heated to be vaporized by the heating device 70c. The vaporized precursor is transported into the mixing-chamber 40. In some embodiments, the reactant is liquid or solid, another heating device can be configured to facilitate the vaporization of the reactant.

In other embodiments, having the precursor and the inert gas mixed first before transported to the mixing-chamber by adding transporting-pipes configured to connect the material-supply device to gas-tank.

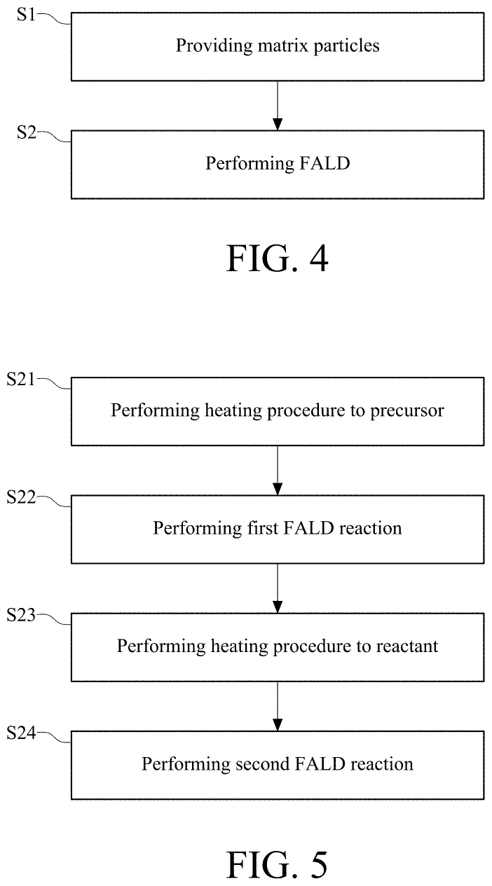

The following is an example of performing a coating method by the apparatus illustrated in FIG. 1 according to one embodiment of the present disclosure. Please refer to FIG. 1, FIG. 2 and FIG. 4. FIG. 4 is a coating process according to one embodiment of the present disclosure. In this embodiment, the coating method includes steps S1 through S2.

Step S1, a plurality of matrix particles P are provided. As shown in FIG. 1, the matrix particles P are delivered into the reaction-chamber 510 from an inlet 511 of the reactor 50. The matrix particles P, for example but not limited to, is electrode material.

Step S2, a FALD is performed on the suspended matrix particles P, and the precursor and the reactant undergo ALD reaction on the surface of the matrix particles P to obtain film-coated matrix particles P. FIG. 5 is a FALD flowchart in FIG. 4. In this embodiment, the FALD includes steps S21 through S24.

Step S21, a heating procedure is performed to the precursor, and the precursor is heated to a FALD temperature. In this embodiment, the precursor is heated several times to reach the FALD temperature. Referring to FIG. 1, the precursor (for example, ammonia) flows into the mixing-chamber 40 through the transporting-pipe 120. The inert gas (for example, nitrogen) flows into the mixing-chamber 40 through the transporting-pipe 220. After the precursor and the inert gas are mixed uniformly in the mixing-chamber 40, the mixed gas flows into the heating device 70a through the transporting-pipe 710b of the heating device 70b. When the precursor and the inert gas pass through the transporting-pipe 710b, the heater 720b heats the precursor and the inert gas to increase their temperature. Moreover, when the precursor and the inert gas flow into the heating-chamber 710a of the heating device 70a, the heater 720a heats the gas to further elevate the gas temperature to FALD temperature. In FIG. 3, the precursor is liquid or solid, the precursor and the inert gas are firstly vaporized by the heating device 70c, and then flow into the mixing-chamber 40 through the transporting-pipe 120.

Step S22, a first FALD reaction is performed, wherein a gas mixture is provided at a fluidization velocity to suspend the matrix particles P, and the precursor reacts with the surface of the matrix particles P to form an adsorption layer. Referring to FIG. 1, the heated gas mixture from step S21, flows into the inbound-chamber 310 of the distribution device 30 and further downward to the reaction-chamber 510 of the reactor 50. The gas mixture in the reaction-chamber 510 causes the matrix particles P to be fluidized; meanwhile, the precursors are adsorbed on the surface of the fluidized matrix particles P to form an adsorption layer. The inert gas acts as a carrier to help fluidize the matrix particles P, and does not undergo any chemical reaction with the matrix particles P. When the first FALD reaction is performed, the heater 520 of the reaction-chamber 510 continuously heated to maintain the FALD temperature in the reaction-chamber 510.

After the first FALD reaction is completed, the residual precursor is purged from the reaction-chamber 510. Specifically, the supply of precursor reaction-chamber is stopped, and the inert gas is continuously introduced from the gas-tank 210 to the heating-chamber 710a, the inbound-chamber 310 and the reaction-chamber 510 in order i.e., the inert gas removes the residual precursor and keep the matrix particles P fluidized. In other embodiments, a pump may be used to purge the residual precursor from the inbound-chamber 310 and the reaction-chamber 510.

Step S23, a heating process is performed to the reactant. The reactant (for example, acetylene) flows into the mixing-chamber 40 through the transporting-pipe 120, and the inert gas (for example, nitrogen) enters the mixing-chamber 40 through the transporting-pipe 220. The gas mixture flows from the mixing-chamber 40 to the heating device 70a through the transporting-pipe 710b of the heating device 70b. When the reactant and the inert gas pass through the transporting-pipe 710b, the heater 720b heats the reactant and the inert gas to increase the gas temperature. After the reactant and the inert gas flow into the heating-chamber 710a of the heating device 70a, the heater 720a heats to further elevate the gas to FALD temperature.

In this embodiment, the precursor and the reactant are heated to the FALD temperature by multiple heating devices. This heating method helps to avoid temperature gradient between the peripheral area and the central area of the heated chamber. However, the present disclosure is not limited by multiple heating. In other embodiments, single heater is configured for a small apparatus, where the problem of uneven gas temperature distribution is less obvious. Furthermore, in other embodiments, the FALD can be performed at room temperature, no heating device is necessary to heat r the precursor or the reactant.

Step S24, a second FALD reaction is performed, and the gas mixture is distributed at a fluidization velocity to suspend the matrix particles P and the reactant reacts with the adsorption layer on the surface of each of the matrix particles P. The heated gas mixture from step S23, flows into the inbound-chamber 310 of the distribution device 30, and the reaction-chamber 510 at the fluidized flow via the distribution unit 320. The gas mixture in the reaction-chamber 510 cause the matrix particles P to be fluidized; meanwhile, the reactants react with the adsorption layer to form a thin film on the surface of each of the matrix particles P. In one embodiment, the precursor is ammonia, the reactant is acetylene, and a graphene film is formed on the matrix particles. When the second FALD reaction is performed, the FALD temperature is maintained in the reaction-chamber 510.

In the first and second FALD reactions of this embodiment, considered to reduce production cost and improve operation safety, a mixed fluid of a precursor and an inert gas and a mixed fluid of a reactant and an inert gas sequentially introduce into the reaction-chamber 510 and FALD is performed, and the matrix particles are suspended by an inert gas, but the present disclosure is not limited thereto. In other embodiments, the FALD matrix particles may be accomplished by the introduction of precursor and reactant, and the residual precursor or reactant can be purged with the inert gas.

After the FALD process is completed, the inert gas is introduced with a higher volume to facilitate film-coated matrix particles P exit the reaction-chamber 510 and enter the collectors 60a, 60b and finally rotate down to the collection tank.

Said FALD temperature can be 650° C. or higher, preferably in the range of 650° C. to 1000° C.; and the result is better when the temperature is from 650° C. to 800° C. When the temperature is less than 650° C., the film-coated matrix particles P have uneven thickness and more amorphous solid with low electrical conductivity. When the temperature is higher than 800° C., a temperature control system of the coating apparatus 1 is easy to overshoot, and not good for automation.

Several embodiments with specific parameters are provided below to illustrate the coating method of the present disclosure and verify the effectiveness of the FALD disclosed in the present disclosure.

### [1st Embodiment]

10 kg of matrix particles are introduced into the reaction-chamber 510 of the reactor 50 in FIG. 1. In this embodiment, the matrix particles are LiNiₓCo_{y}Al_{z}O₂ particles. The particles size is 0.5 micrometer to 10 micrometers, a specific capacity is about 150 mAh/g, a tapping density is greater than 2.3 g/cm³, and a BET is around 0.5 m²/g.

Ammonia gas is introduced into the mixing-chamber 40 from the material-supply device 10 at a flow rate of 30 L/min. Moreover, nitrogen gas is introduced into the mixing-chamber 40 from the gas-supply device 20 at a flow rate of 10 L/min, and the nitrogen gas and ammonia gas are mixed uniformly in the mixing-chamber 40. The gas mixture flows from the mixing-chamber 40 into the heating device 70a through the transporting-pipe 710b of the heating device 70b. When the gas mixture passes through the transporting-pipe 710b, the heater 720b of the heating device 70b heats the gas mixture to 200° C. After the gas mixture flows into the heating-chamber 710a of the heating device 70a, the heater 720a heats the gas mixture to 650° C.

Next, the first FALD reaction is performed. That is, the gas mixture containing the ammonia and the nitrogen flows from the heating device 70a into the inbound-chamber 310 of the distribution device 30. The distribution unit 320 of the distribution device 30 distributes the gas mixture containing the ammonia and the nitrogen from the inbound-chamber 310 into the reaction-chamber 510 of the reactor 50 and thus the LiNiₓCo_{y}Al_{z}O₂ particles are fluidized by the gas mixture. The ammonia reacts with the surface of the LiNiₓCo_{y}Al_{z}O₂ particles and form an adsorption layer, and the reaction time is 1 minute. When the first FALD reaction is performed, the temperature of the reaction-chamber 510 keeps at 750° C. After the first FALD reaction is completed, nitrogen gas is introduced to the inbound-chamber 310 and the reaction-chamber 510 to remove residual ammonia.

Acetylene is introduced into the mixing-chamber 40 from the material-supply device 10 at a flow rate of 30 L/min. Moreover, nitrogen gas is introduced into the mixing-chamber 40 from the gas-supply device 20 at a flow rate of 10 L/min, and the nitrogen gas and acetylene are uniformly mixed in the mixing-chamber 40. The gas mixture flows from the mixing-chamber 40 into the heating device 70a through the transporting-pipe 710b of the heating device 70b. When the gas mixture passes through the transporting-pipe 710b, the heater 720b of the heating device 70b heats the gas mixture to 200° C. After the gas mixture flows into the heating-chamber 710a of the heating device 70a, the heater 720a heats the gas mixture to 650° C.

Next, the second FALD reaction is performed. That is, the gas mixture of acetylene and the nitrogen are introduced from the heating device 70a into the inbound-chamber 310 of the distribution device 30. The distribution unit 320 of the distribution device 30 distributes the said gas mixture from the inbound-chamber 310 into the reaction-chamber 510 of the reactor 50 and the LiNiₓCo_{y}Al_{z}O₂ particles are fluidized by the mixture. The acetylene reacts with the adsorption layer on the surface of the LiNiₓCo_{y}Al_{z}O₂ particles, such that the nitrogen atom is replaced by a carbon atom and a single layer graphene film is formed on the surface of the LiNiₓCo_{y}Al_{z}O₂ particles. The reaction time is 1 minute. When the second FALD reaction is performed, the heater 520 keeps the temperature of the reaction-chamber 510 at 750° C. After the second FALD reaction is performed, nitrogen gas is introduced to the chamber 310 and the reaction-chamber 510 to remove residual acetylene.

After the first and second FALD reaction are performed in order, one FALD cycle is completed. Then, the first and second FALD reaction are performed repeatedly for multiple FALD cycles. In this embodiment, fifteen FALD cycles are performed, coating 2-3 nm thickness graphene on the surface of the LiNiₓCo_{y}Al_{z}O₂ particles. This is the coated electrode material of the first embodiment.

After the FALD cycles are completed, huge amount of nitrogen gas is injected into the reaction-chamber 510. The coated electrode material moves with the nitrogen gas flow into the collectors 60a, 60b. The coated electrode material collides with the inner wall of the collectors 60a, 60b and is collected in the storage tank.

### 2nd Embodiment

The 2nd embodiment is similar to the 1st embodiment except that the second embodiment performs 25 FALD cycles

### 3rd Embodiment

The 3rd embodiment is similar to the 1st embodiment, except that the 3rd embodiment performs 50 FALD cycles.

### 4th Embodiment

The 4th embodiment is similar to the 1st embodiment, except that the 4th embodiment performs 75 FALD cycles.

### 5th Embodiment

The 5th embodiment is similar to the 1st embodiment, except that the 5th embodiment performs 100 FALD cycles.

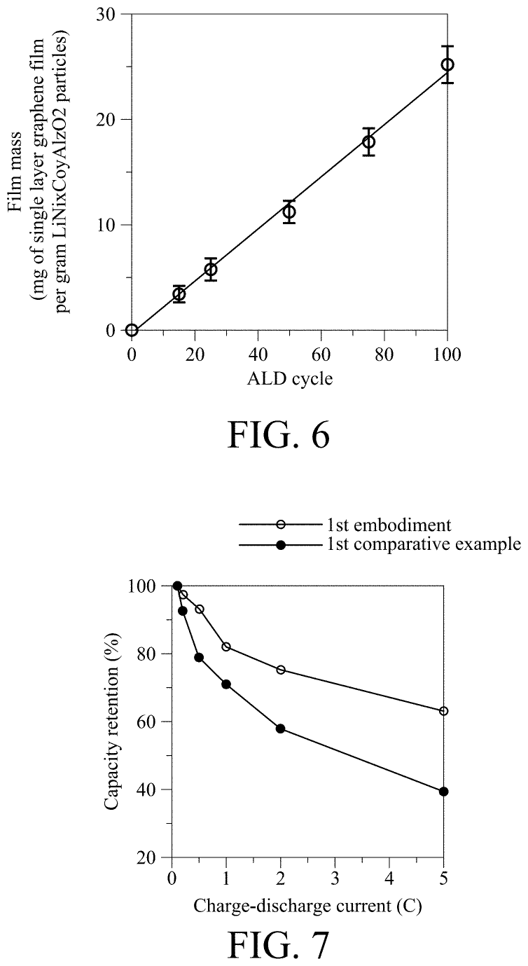

FIG. 6 is a graph of film mass against FALD cycle. As the number of FALD cycle increases, the thickness of graphene film on the surface of LiNiₓCo_{y}Al_{z}O₂ particles increases. In the first embodiment, the average graphene mass is 3 mg per gram of LiNiₓCo_{y}Al_{z}O₂ particles in the second embodiment, the average graphene mass is 7 mg per gram of LiNiₓCo_{y}Al_{z}O₂ particles. In the third embodiment, the average graphene mass is 11 mg per gram of LiNiₓCo_{y}Al_{z}O₂ particles. In the 4th embodiment, the average graphene mass is 17.5 mg per gram of LiNiₓCo_{y}Al_{z}O₂ particles. In the 5th embodiment the average graphene mass is 25 mg per gram of LiNiₓCo_{y}Al_{z}O₂ particles.

Two comparative examples are further provided below to illustrate the effectiveness of the present disclosure on the improvement of capacity and lifetime of lithium battery

### 1ST COMPARATIVE EXAMPLE

The 1st comparative example is similar to the first embodiment, except that there is no graphene layer on the surface of the LiNiₓCo_{y}Al_{z}O₂ particles.

### 2ND COMPARATIVE EXAMPLE

The 2nd comparative example is similar to the 1st embodiment, except that the second comparative example uses a conventional FBR to form a graphene layer on the surface of the LiNiₓCo_{y}Al_{z}O₂ particles.

FIG. 7 is a graph of capacity retention of battery including film-coated electrode versus charge-discharge current. The cathode of coin-cell lithium battery, is made of the LiNiₓCo_{y}Al_{z}O₂ particles coated with a graphene film in the 1st embodiment, a 5C current is applied to charge/discharge several times, and the capacity retention of the coin-cell lithium battery is about 68%. However, the cathode of a coin-cell lithium battery, is made of the LiNiₓCo_{y}Al_{z}O₂ particles in the 1st comparative example, and a 5C current is applied for the same charge cycles, the capacity retention of the coin-cell lithium battery is only 40%.

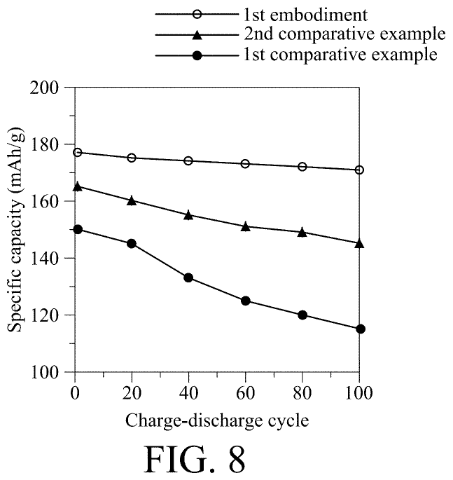

FIG. 8 is a graph of specific capacity of battery including film-coated electrode 1 versus charge-discharge cycles. A cathode of the lithium battery is made of the LiNiₓCo_{y}Al_{z}O₂ particles coated with graphene film in the 1st embodiment, an initial specific capacity of the cathode is about 178 mAh/g. After applying 100 charge-discharge cycles at 0.5 C, the specific capacity of the cathode is about 172 mAh/g. Contrast to a cathode of the lithium battery is made of the LiNiₓCo_{y}Al_{z}O₂ particles in the 1st comparative example, an initial specific capacity of the cathode is about 150 mAh/g. After applying 100 times charge-discharge cycles at 0.5 C, the specific capacity of the cathode is about 116 mAh/g. As to a cathode of the lithium battery, is made of the LiNiₓCo_{y}Al_{z}O₂ particles in the 2nd comparative example, an initial specific capacity of the cathode is about 165 mAh/g. After applying 100 charge-discharge cycles at 0.5 C, the specific capacity of the cathode is about 147 mAh/g.

According to FIG. 7, compared to the LiNiₓCo_{y}Al_{z}O₂ particles without coated film, the LiNiₓCo_{y}Al_{z}O₂ particles coated graphene improve the capacity retention of a lithium battery and increase battery lifetime. According to FIG. 8, compared to the uncoated LiNiₓCo_{y}Al_{z}O₂ particles, a film-coated LiNiₓCo_{y}Al_{z}O₂ particles by FBR, the graphene-coated LiNiₓCo_{y}Al_{z}O₂ by FALD process is favorable for obtaining a higher initial specific capacity of the cathode for the lithium battery, and the specific capacity decreases slowly even after many charge-discharge cycles.

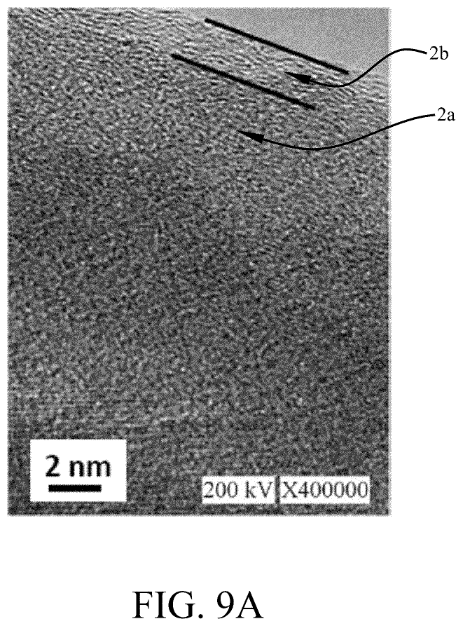

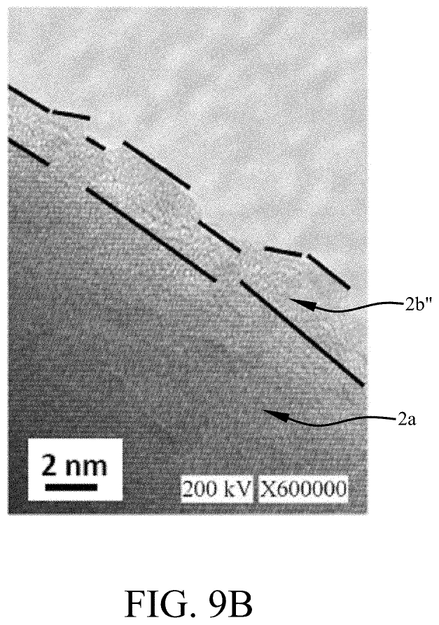

FIG. 9A is a SEM image of a film-coated electrode material fabricated by the coating method in FIG. 4. FIG. 9B is a SEM image of film-coated electrode material fabricated by conventional FBR. The SEM image in FIG. 9A shows a graphene film 2b formed on a LiNiₓCo_{y}Al_{z}O₂ particles 2a by FALD, and the SEM image in FIG. 9B shows a graphene film 2b″ formed on the LiNiₓCo_{y}Al_{z}O₂ particle 2a by FBR. Referring to FIG. 9A and FIG. 9B, the graphene film 2b formed by FALD has a uniform thickness.

According to the present disclosure, the coating apparatus and the coating method can be applied to different matrix particles for coating different films. The matrix particle can be photoelectric materials (such as ceramic powders), antistatic coatings (such as iron powder, cobalt powder, nickel powder), or insulating coatings (such as boron nitride or titanium oxide). Also, the matrix particles are not limited to powder, flake or rod.

According to the present disclosure, a film-coated electrode material manufactured by FALD. Compared to the electrode material without film coating, the lithium battery including film coating electrode material features higher battery capacity and longer lifetime.

Furthermore, compared to the film-coated matrix particles by conventional FBR, the FALD of the present disclosure forms high quality film with even thickness on the matrix particles, and such coated film is not easy to break or peel from the surface of the matrix particles.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A coating apparatus, comprising:
a material-supply device supplying a precursor and a reactant;
a distribution device connected to the material-supply device; and
a reactor connected to the distribution device, the distribution device is configured to distribute the precursor and the reactant into the reactor.

2. The coating apparatus of claim 1, wherein the distribution device comprises an inbound-chamber and a distribution unit, and the inbound-chamber is connected to the reactor via the distribution unit.

3. The coating apparatus of claim 2, wherein the distribution unit comprises a plurality of spray nozzles spaced apart from each other.

4. The coating apparatus of claim 1, wherein the reactor comprises a reaction-chamber and a heater disposed on the reaction-chamber.

5. The coating apparatus of claim 1, further comprising a first heating device disposed on a fluid transport path between the material-supply device and the distribution device.

6. The coating apparatus of claim 5, further comprising a second heating device disposed on a fluid transport path between the first heating device and the material-supply device.

7. The coating apparatus of claim 6, further comprising a third heating device disposed on the material-supply device.

8. The coating apparatus of claim 1, further comprising at least one collector connected to the reactor.

9. The coating apparatus of claim 8, wherein the at least one collector comprises a first collector and a second collector, the first collector is connected to the reactor, and the second collector is connected to the first collector.

10. The coating apparatus of claim 1, further comprising a mixing-chamber disposed on a fluid transport path between the material-supply device and the distribution device.

11. The coating apparatus of claim 1, further comprising a gas-supply device connected to the distribution device.

12. A coating method, comprising:
providing a matrix particle; and
performing a fluidized atomic layer deposition (FALD), wherein a mixture containing a precursor and an inert gas and a mixture containing a reactant and the inert gas are provided at a fluidization velocity so as to suspend the matrix particle, the precursor and the reactant react on a surface of the matrix particle so as to obtain a film coating matrix particle.

13. The coating method of claim 12, wherein the FALD comprises:
performing a first FALD reaction, wherein the mixture containing the precursor and the inert gas is provided at the fluidization velocity so as to suspend the matrix particle, and the precursor reacts with the surface of the matrix particle so as to form an adsorption layer; and
performing a second FALD reaction, wherein the mixture containing the reactant and the inert gas is provided at the fluidization velocity so as to suspend the matrix particle, and the reactant reacts with the adsorption layer.

14. The coating method of claim 12, further comprising:
performing a heating procedure to the precursor and the reactant, the precursor and the reactant are heated to an FALD temperature.

15. The coating method of claim 14, wherein the FALD temperature is greater than or equal to 650° C.
